(19) United States
(12) Patent Application Publication
(10) Pub. No.: US 2026/0071349 A1
(43) Pub. Date: Mar. 12, 2026

(54) CRYSTAL GROWTH MACHINE LEARNING SYSTEM

(71) Applicant: Katherine E. Colbaugh, Cleveland Heights, OH (US)

(72) Inventor: Katherine E. Colbaugh, Cleveland Heights, OH (US)

(21) Appl. No.: 19/202,011

(22) Filed: May 8, 2025

Related U.S. Application Data
(60) Provisional application No. 63/645,455, filed on May 10, 2024.

(51) Int. Cl. C30B 15/20; G05B 13/02; G05B 13/04

(52) U.S. Cl. CPC C30B 15/20; G05B 13/0265; G05B 13/048

(57) ABSTRACT

A system for crystal growth optimization includes a plurality of sensors integrated into crystal growth equipment for continuous monitoring and data collection, a data acquisition device for receiving data from the sensors, a computing system for storing and processing the received data, a machine learning algorithm implemented on the computing system for analyzing the received data and predicting process improvements, and a user interface for displaying real-time data, process trends, root-cause analysis of defects, and suggested process improvements. The sensors may include various types such as viscometers, pH meters, thermometers, and imaging sensors. The machine learning algorithm may be selected from Linear Regression, Logistic Regression, Neural Network, and Decision Tree algorithms. The system enables automated adjustments of crystal growth parameters and utilizes historical and crowdsourced data to enhance prediction accuracy across different materials and growth conditions.

### CROSS-REFERENCE TO RELATED APPLICATIONS

This application is a Utility Patent application claiming priority to U.S. Provisional Patent Application Ser. No. 63/645,455, filed on May 10, 2024, which is incorporated by reference herein in its entirety.

### COPYRIGHT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

Trademarks used in the disclosure of the invention, and the applicants, make no claim to any trademarks referenced.

### BACKGROUND OF THE INVENTION

### 1) Field of the Invention

The invention relates to the field of crystal growth production, and more specifically to a crystal growth machine learning (ML) system for continuous monitoring, in-process and run-to-run adjustments, data analysis, and process improvement of industrial-scale crystal growth production.

### 2) Description of Related Art

Crystal growth is a highly technical process required for the manufacturing of materials that are the critical components in products across a range of industries. Current crystal growth methods require highly trained and experienced technical staff to run production and related engineering efforts. Crystal growth is an inherently complicated process with significant safety risks. A lack of trained personnel and challenging, time intensive, low yield crystal growth processes are creating a gap in the supply chain. To address these issues, a system is needed to accelerate process improvements, optimize crystal growth, reduce training time, and minimize current required root-cause-analysis and trail-and-error based process engineering efforts.

Crystal growth is a process that involves the controlled solidification of a material to form an ordered solid. This process can be initiated from various states of matter including vapor, liquid, or solid start materials. The resulting crystals are solid materials composed of atoms, ions, or molecules arranged in an orderly pattern that is repeated uniformly throughout the volume of the material.

Crystals are utilized in a wide range of industries including transportation, telecommunication, medical imaging and treatment, pharmaceuticals, oil and gas, industrial inspection and manufacturing, alternative energy, space exploration, geology, aerospace and defense, nuclear detection, high energy physics, jewelry, and homeland security. The functionality of crystals can be classified into categories such as semiconductors, scintillators, nonlinear crystals, optics and photonics, and organic crystals.

The manufacturing of crystals involves specific growth methods that are selected based on the type of crystal, the temperature and pressure conditions for solidification, and the desired purity and quality of the resulting crystal. These methods require high levels of data recording and process control to ensure repeatability. The data recorded includes information about the composition and purity of starting materials, seed crystal composition and orientation, crucible characteristics, temperature conditions, humidity, weight, composition, interface shape, size of crystal, conductivity, pH, solubility, environmental gas composition, flow rate, rotation rate, growth rate, pull speed, viscosity, stirring speed, ultrasound, magnetic field, irradiation, additives, and pressure.

Inspection methods are employed during and after the growth process, and during the fabrication and production of the crystal product. These methods involve measurements of controlled parameters, imaging, and X-ray measurements. Post-growth inspection data includes visual quality, defect concentration, percent yield, weight, size, conductivity, microscopy and spectroscopy measurements, orientation, dissolution data, composition, electronic properties, and optical properties.

The crystal growth industry faces challenges related to yield, with typical production yields often below 30% of the starting material. This low yield results from failed growth runs and various defects in crystals, leading to significant material and resource losses. The process can be resource-intensive, involving high costs related to growth apparatus, energy consumption, specialized materials, and extensive labor.

Currently, the crystal growth industry relies heavily on a small community of highly experienced professionals, including engineers, physicists, chemists, and crystal growth scientists, to design and maintain crystal growth processes. These experts are responsible for various aspects of production, including process design, material analysis, research, troubleshooting, and continuous improvement efforts.

The field faces challenges related to the complex nature of crystal growth, the reliance on specialized knowledge, and the potential loss of critical information due to the dependence on individual expertise. Additionally, the time-consuming nature of establishing and refining crystal growth manufacturing facilities, often requiring years of trial-and-error experimentation, presents obstacles to rapid advancements in the field.

As the demand for high-quality crystals continues to grow across various industries, there is a need for advancements in crystal growth technology that can address these challenges, improve yields, and enhance the efficiency and consistency of crystal production processes.

### BRIEF SUMMARY OF THE INVENTION

The instant invention in one form is directed to a crystal growth optimization system including a plurality of sensors integrated into crystal growth equipment for continuous monitoring and data collection. The system also includes a data acquisition device for receiving data from the sensors and control modules, a computing system for storing and processing the received data, and machine learning algorithms implemented on the computing system for analyzing the received data, making in-process adjustments of controls and predicting process improvements. If multiple crystal growth equipment stations are running similar processes, the stations will be networked such that data from each station may be integrated into the machine learning system. The data from an individual station may be analyzed with historical data from that station or with historical and/or real-time data from similar stations. The system further includes a user interface for displaying real-time data, comparison of real-time data to historical data, analysis of individual and/or grouped equipment stations, process trends, root-cause analysis of defects, correlation of process parameters to material properties and output results, and suggested process improvements.

According to other aspects of the present disclosure, the method may include at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer as part of the plurality of sensors. The control modules include process control systems, power output, programmable logic controllers (PLCs), proportional-integral-derivative (PID), digital or analog input controls, motor controls, valve controls, temperature controls, gas flow controls, pressure controls, water controls. The machine learning algorithm may be selected from the group consisting of Linear Regression, Deep Learning, Physics-Informed, Logistic Regression, Neural Network, Classification, and Decision Tree algorithms. The data from the sensors may be hardwired or wirelessly transmitted to the computing system. The machine learning algorithms may be configured to make data-based decisions using historical data, crowdsourced data, and experiential knowledge. The machine learning algorithms may incorporate theoretical equations and may be guided or configured based on physical, chemical, thermodynamic, and mechanical interactions related to the crystal growth process. The user interface may be accessible via a close-loop on-site network, secure web login, or a phone app interface. The user interface may be configured to display real-time data for each running crystal growth setup including plots of measurements, likelihood of success, and dials for manual adjustment of controls. The user interface may display analysis in the form of text or visualizations including pair plots, scatter plots, bar charts, line charts, histograms, box plots, heatmaps, regression analysis plots, feature importances plot, recursive feature elimination plots, elbow plots, scree plots, learning curves, and validation curves.

According to yet another aspect of the present disclosure, a crystal growth optimization system includes a plurality of sensors and control modules for monitoring and controlling a crystal growth process and collecting data during the process. The system includes a data acquisition device for receiving the collected data, control modules for controlling the process and system components, a computing system for storing and processing the received data, a machine learning algorithm implemented on the computing system for analyzing the received data, identifying process trends and root-cause of defects, and predicting process improvements, and a user interface for displaying the real-time data, process trends, root-cause analysis of defects, and suggested process improvements. The system automatically adjusts process controls based on in-process measurements and historical data analysis.

One aspect is directed to a system for crystal growth optimization. The system includes a plurality of sensors integrated into crystal growth equipment for continuous monitoring and data collection. The system includes a data acquisition device for receiving data from the sensors, a computing system for storing and processing the received data, and a machine learning algorithm implemented on the computing system for analyzing the received data and predicting process improvements. The system includes control modules for controlling the process and components within the system. The system includes a user interface for displaying real-time data, process trends, root-cause analysis of defects, and suggested process improvements. The plurality of sensors may include at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer. The machine learning algorithm may implement any combination of Linear Regression, Logistic Regression, Neural Network, and Decision Tree algorithms. The system may include a module for automatically adjusting crystal growth parameters based on the predicted process improvements. The automatically adjusted crystal growth parameters may include at least one of temperature, rotation speed, pull speed, and pressure. The system may include a data storage system for storing historical crystal growth data and crowdsourced data from multiple crystal growth facilities. The machine learning algorithm may use the historical crystal growth data and crowdsourced data to enhance prediction accuracy of process improvements across different materials and growth conditions.

Another aspect is directed to a method for optimizing crystal growth. The method includes continuously monitoring crystal growth parameters using a plurality of sensors integrated into crystal growth equipment and collecting data from the sensors using a data acquisition device. The method includes processing the collected data using a computing system, The method includes analyzing the processed data using a machine learning algorithm to predict process improvements and displaying real-time data, process trends, root-cause analysis of defects, and suggested process improvements on a user interface. The plurality of sensors may include at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer. The machine learning algorithm may implement any combination of Linear Regression, Logistic Regression, Neural Network, and Decision Tree algorithms. The method may implement a module for automatically adjusting crystal growth parameters based on the predicted process improvements. The automatically adjusted crystal growth parameters may include at least one of temperature, rotation speed, pull speed, and pressure. The method may include use of a data storage system for storing historical crystal growth data and crowdsourced data from multiple crystal growth facilities. The machine learning algorithm may use the historical crystal growth data and crowdsourced data to enhance prediction accuracy of process improvements across different materials and growth conditions.

Another aspect is directed to a non-transitory computer-readable medium storing instructions that, when executed by a processor, cause the processor to perform operations for crystal growth optimization. The operations include receiving data from a plurality of sensors integrated into crystal growth equipment and storing and processing the received data. The operation includes analyzing the processed data using a machine learning algorithm to predict process improvements and generating output for display on a user interface, the output including real-time data, process trends, root-cause analysis of defects, and suggested process improvements. The plurality of sensors may include at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer. The machine learning algorithm may implement any combination of Linear Regression, Logistic Regression, Neural Network, and Decision Tree algorithms. The instructions may implement a module for automatically adjusting crystal growth parameters based on the predicted process improvements. The automatically adjusted crystal growth parameters may include at least one of temperature, rotation speed, pull speed, and pressure. The instructions may implement a data storage system for storing historical crystal growth data and crowdsourced data from multiple crystal growth facilities. The machine learning algorithm may use the historical crystal growth data and crowdsourced data to enhance prediction accuracy of process improvements across different materials and growth conditions.

These and other objects, features, and advantages of the present invention will become more readily apparent from the attached drawings and the detailed description of the preferred embodiments, which follow.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. When reference is made to a reference numeral without specification to an existing sub-label, it is intended to refer to all such multiple similar components.

FIG. 1 is a schematic diagram showing a method of crystal growth according to the present invention;

FIG. 2 shows a vapor deposition growth control diagram and thermal modeling;

FIG. 3 is an overview of crystal growth machine learning system;

FIG. 4A shows a chart of an example scatter plot with regression analysis, heat map, pair plot, and random forest feature importance;

FIG. 4B shows another chart of an example visualization including numerical representations and shading;

FIG. 4C shows another chart of an example group of plots and curves;

FIG. 4D shows a line graph of crystal growth parameters;

FIG. 5 is a flowchart comparing current state of the art to the crystal growth ML system according to the present invention; and

FIG. 6 shows an example neural network diagram for the crystal growth of an optical crystal.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION

While various aspects and features of certain embodiments have been summarized above, the following detailed description illustrates a few exemplary embodiments in further detail to enable one skilled in the art to practice such embodiments. The described examples are provided for illustrative purposes and are not intended to limit the scope of the invention.

In the following description, for the purposes of explanation, numerous specific details are set forth in order to provide a thorough understanding of the described embodiments. It will be apparent to one skilled in the art however that other embodiments of the present invention may be practiced without some of these specific details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

In this application the use of the singular includes the plural unless specifically stated otherwise and use of the terms “and” and “or” is equivalent to “and/or,” also referred to as “non-exclusive or” unless otherwise indicated. Moreover, the use of the term “including,” as well as other forms, such as “includes” and “included,” should be considered non-exclusive. Also, terms such as “element” or “component” encompass both elements and components including one unit and elements and components that include more than one unit, unless specifically stated otherwise.

Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps or acts are in some way inherently mutually exclusive.

As this invention is susceptible to embodiments of many different forms, it is intended that the present disclosure be considered as an example of the principles of the invention and not intended to limit the invention to the specific embodiments shown and described.

Crystal growth is a highly technical process required for the manufacturing of materials that are the critical components in products across a range of industries. Current crystal growth methods require highly trained and experienced technical staff to run production and related engineering efforts. Crystal growth is an inherently complicated process with significant safety risks. A lack of trained personnel and challenging, time intensive, low yield crystal growth processes are creating a gap in the supply chain. To address these issues, a novel system is presented here to accelerate process improvements, optimize crystal growth, reduce training time, and minimize current required root-cause-analysis and trail-and-error based process engineering efforts.

Crystals are solid materials composed of atoms, ions, or molecules in an orderly pattern that is repeated uniformly throughout the entire volume. Commonly known crystals are table salt (NaCl) and quartz (SiO₂). The applications for crystals include the following industries: transportation, telecommunication, medical imaging and treatment, pharmaceutical, oil and gas, industrial inspection and manufacturing, alternative energy, space exploration, geology, aerospace and defense, nuclear detection, high energy physics, jewelry, and homeland security. For example, modern cell phone production incorporates at least five different types of single crystals. Crystals are generally classified based on their functionality: semiconductors, scintillators, nonlinear crystals, optics and photonics, and organic crystals.

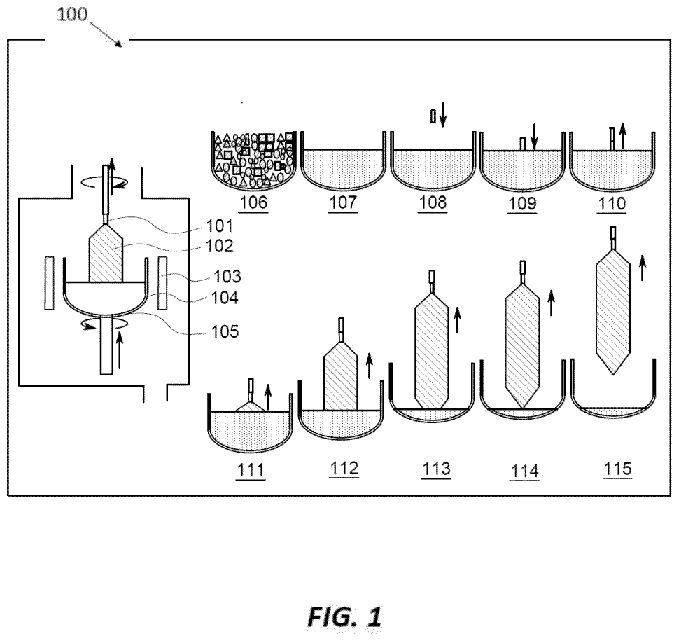

Depending on the functionality and application mentioned above, crystals are manufactured by specific “growth” methods. Crystal growth refers to the controlled solidification of a material such that it forms an ordered solid from vapor (by sublimation-condensation, sputtering, epitaxy, or ion-implantation methods), liquid (by melt, flux, solution, hydrothermal, or gel methods), or solid (by devitrification, strain annealing, polymorphic phase change, or precipitation methods) start materials. Many specific crystal growth techniques have been developed including: Bridgman-Stockbarger, Kyropoulos, Czochralski, Zoning, Edge-defined film-fed growth, Verneuil, continuous feeding, evaporation, slow cooling, boiling, hydrothermal sintering, temperature gradient (normal and reversed), and gel growth by reaction, chemical reduction, solubility reduction, and diffusion. The Czochralski method 100 as shown in FIG. 1, is used in industry where high quality single crystals are required. This method includes melting feed material in a crucible and growing a single crystal by dipping a “seed” into the melt and subsequently rotating and pulling the crystal from the melt. The remainder of this document uses the term “crystal growth” to refer to all methods including, but not limited to, the techniques above.

Crystal Manufacturing Controls—Industrial crystal growth methods, proprietary adaptations of the techniques have been developed to manufacture crystal materials on a large scale. Specific methods are selected based on the type of crystal, temperature and pressure required for solidification, and required purity and quality of the resulting crystal. Crystal manufacturing requires high levels of data recording (by manual or digital methods) and process control to ensure repeatability. Current control data include composition (and purity) of starting materials, seed crystal composition and orientation, crucible (shape, size, and material), crystal growth apparatus, temperature (of furnace, melt, gradient, environment, and annealing), humidity, weight (of melt and/or crystal), composition, interface shape, size of crystal (by weight, length, diameter, width, thickness, distance of travel), conductivity, pH, solubility, environmental gas composition, flow rate, rotation rate, growth rate, pull speed, viscosity, stirring speed, ultrasound, magnetic field, irradiation, additives, and pressure. The general goal of crystal manufacturing is to control as many data points as possible and prevent variability to produce consistent material with quality sufficient for the end application of the product incorporating the crystal.

Crystal Inspection Methods—Crystal manufacturing requires a series of inspection methods during growth, after growth, and during fabrication and production of the crystal product. Inspection data during growth includes measurements of controlled parameters listed above, imaging, and X-ray measurements. Post-growth inspection data include visual quality, defect concentration, percent yield, weight, size, conductivity, microscopy and spectroscopy measurements, orientation, dissolution data, composition, electronic properties, and optical properties. These inspection methods are used throughout the production process to screen material, depending on the application requirements.

The Problem: Safety Risk, Defects, Yield Loss, Intensive Training, Labor Gap—Typical yield in the crystal growth industry is below 30% of the starting material, resulting from failed growth runs and various defects in crystals. This is significant loss, especially considering the intensive crystal growth process that often includes high costs related to growth apparatus, power to high temperatures, rare earth metal crucibles, starting materials and raw material processing, extensive labor, and long growth run times limited by the physical formation of certain materials (anywhere from days to years). In some cases, raw materials can be re-used (with high associated cost of rework), but often failures result in the rejection of an entire crystal growth run.

Because of the extreme growth conditions (high temperatures, dangerous chemical compositions, and high pressures), there are substantial safety risks present in crystal growth processes. Limiting safety concerns and controlling process variables must be carefully executed for each crystal growth run. Technical labor for such processes requires intensive on-the-job experience, a steep learning curve, a high level of reasoning and attention to detail, and exhaustive training that can take years to complete. Ideally, crystal growth stations would be monitored continuously to detect any problems or anomalies in the growth process. Many companies either have a single person or do not have any qualified personnel to complete this work. It is estimated that 67,000 (or 58%) technical jobs will remain unfilled by 2030, in the semiconductor industry alone. For these reasons, crystal growth production often runs at low profit margins with limited resources for much-needed process improvements or research.

The Solution: Complex Troubleshooting, Process Controls—Crystal growth equipment in industry is designed to control specific parameters, such as temperature, and some even provide “automation” in the form of monitoring, feedback loops, and adjustment of controls. Crystal growth process data is collected, either manually or digitally, and stored in varying degrees of details across the industry. Some crystal growth systems even have alarms to indicate temperature failures or power loss.

FIG. 1 illustrates a crystal growth diagram 100 showing various stages of a Czochralski crystal growth process. The crystal growth diagram 100 may include a seed crystal 101, a crystal 102, a heater 103, a melt 104, and a crucible 105. The process may begin with a feed material 106 in a melting stage 107, followed by a seed lowering stage 108, a seed immersion stage 109, and a growth initiation stage 110. The crystal growth may progress through a first growth stage 111, a second growth stage 112, a third growth stage 113, a fourth growth stage 114, and conclude with a final growth stage 115.

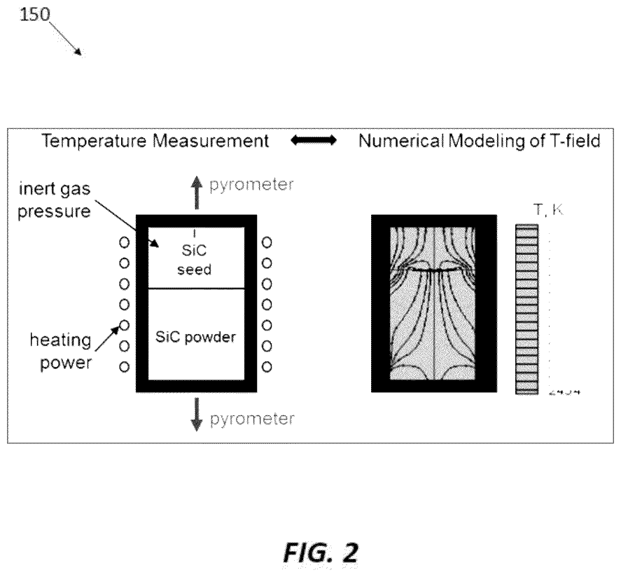

FIG. 2 depicts a vapor deposition system 150, which illustrating temperature measurement and modeling aspects of the crystal growth process.

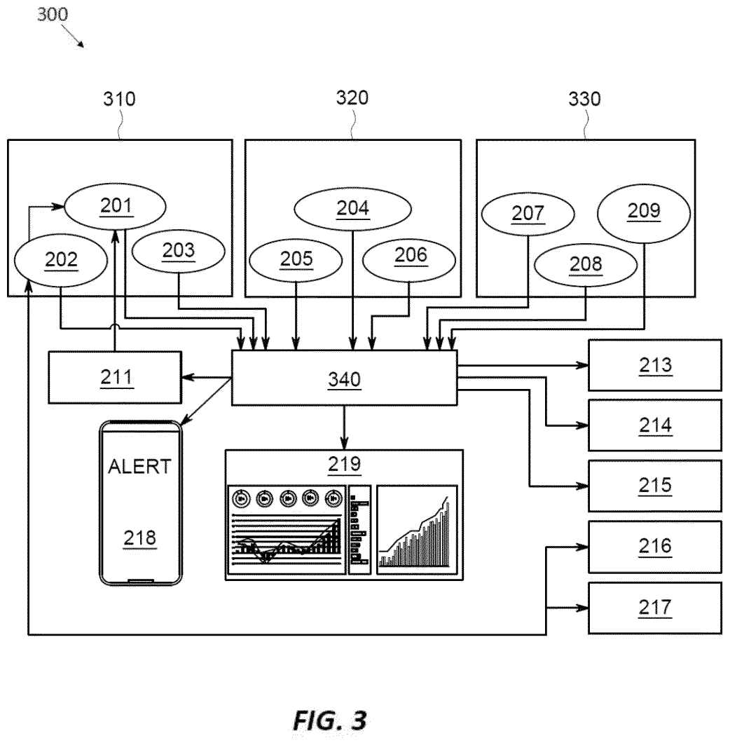

FIG. 3 presents an overview of a crystal growth system 300. The crystal growth system 300 may comprise a crystal growth module 310, a manufacturing module 320, and a process engineering module 330. These modules may interface with a machine learning interface 340, which may process input data and generate various outputs for process optimization. The crystal growth module 310 includes a run setup command 202 to initiate a setup process, sensors 203 which sends data to the crystal growth machine learning system 340, and controls which operate the system process. The manufacturing module 320 manages inspection 204, defects 205 and product yield 206. The process engineering module 330 provides historic information 207, expertise information 208 and crowd-sourcing information 209. The crystal growth machine learning system 340 provides in-process adjustment information 211 to the controls 201 and sends alert information to a mobile device for display to a user. The crystal growth machine learning system 340 communicates with a web user interface 219 so a user can access information on the system. The crystal growth machine learning system 340 is used in performing defect elimination 213, root-cause analysis 214, process improvements 215, trend identification 216, and run-to-run adjustments 217 by continually monitoring through the use of the sensors 203 and adjusting through the controls 201.

The system may include modules similar to one or more of the modules 310, 320, 330 and is not limited to the modules presented.

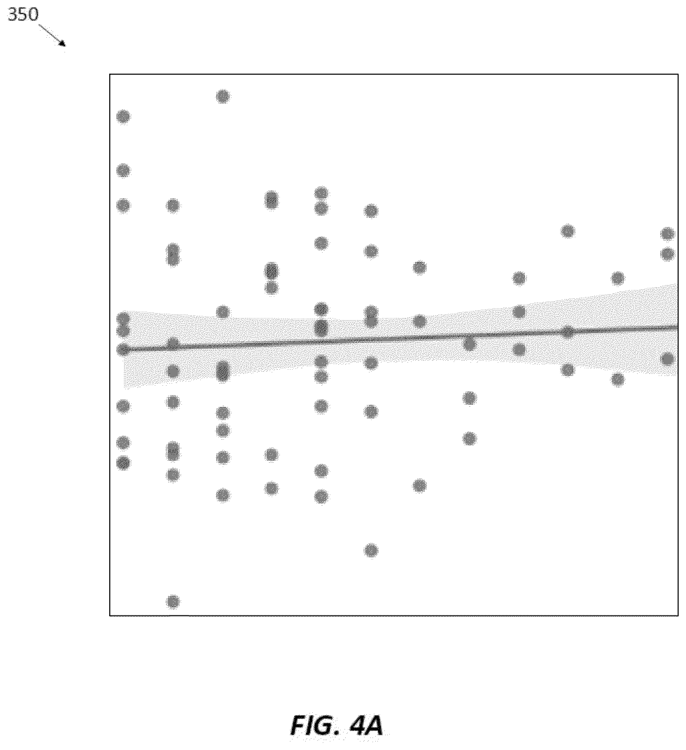

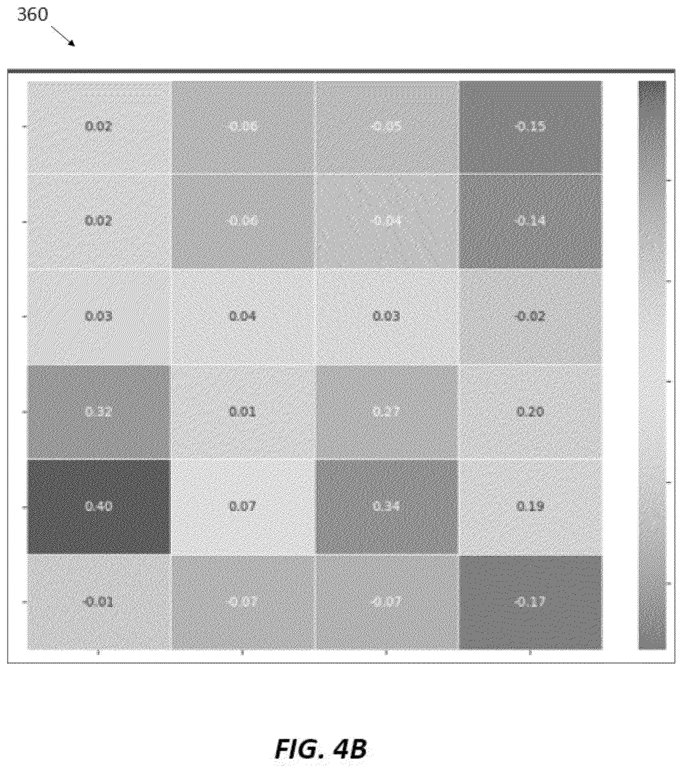

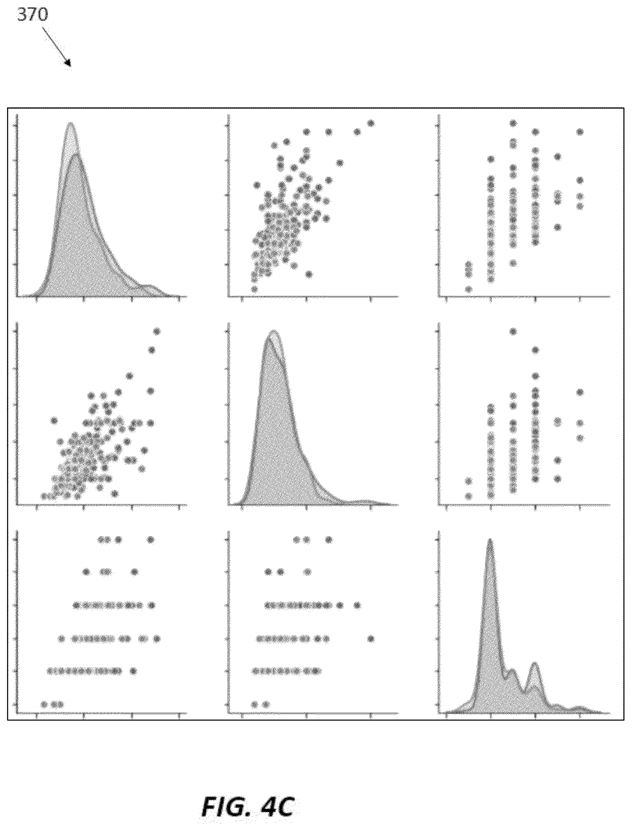

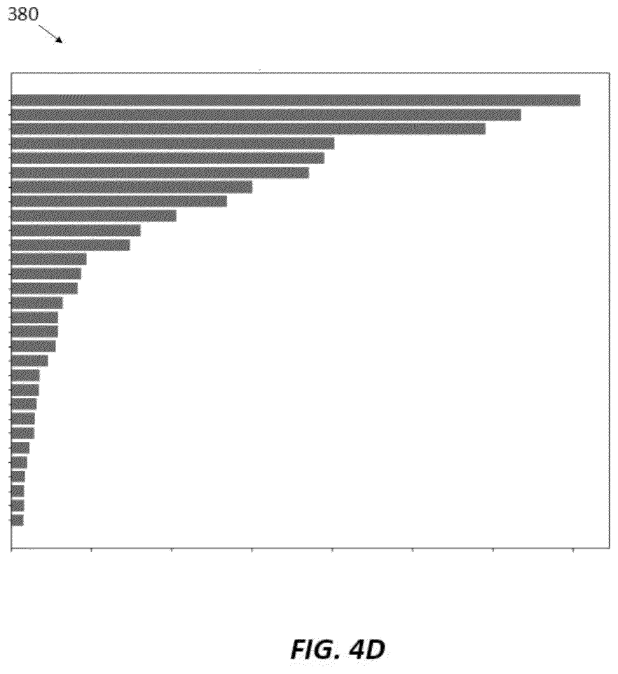

FIG. 4A shows a chart 350 of an example scatter plot with regression analysis, heat map, pair plot, and random forest feature importance;

FIG. 4B shows another chart 360 of an example visualization including numerical representations and shading;

FIG. 4C shows another chart 370 of an example group of plots and curves;

FIG. 4D shows a line graph 380 of crystal growth parameters;

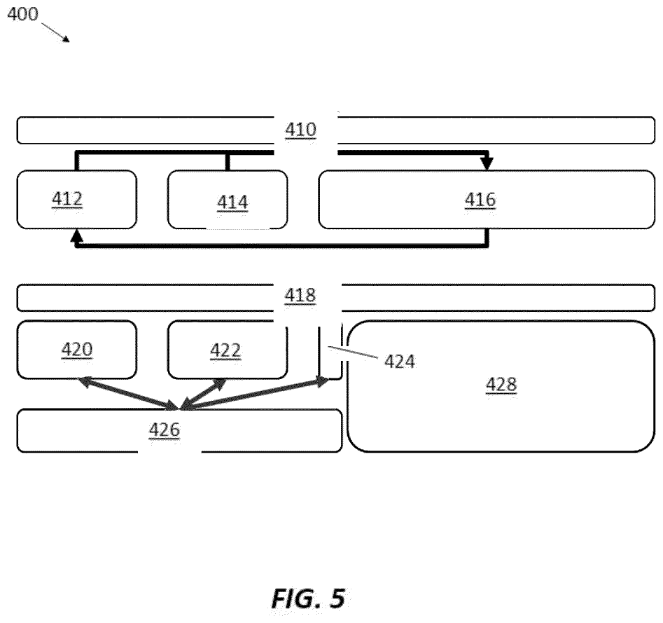

FIG. 5 shows a process comparison diagram 400, contrasting traditional crystal growth processes with the crystal growth machine learning system approach. The diagram may highlight the potential time savings and efficiency improvements offered by the machine learning system.

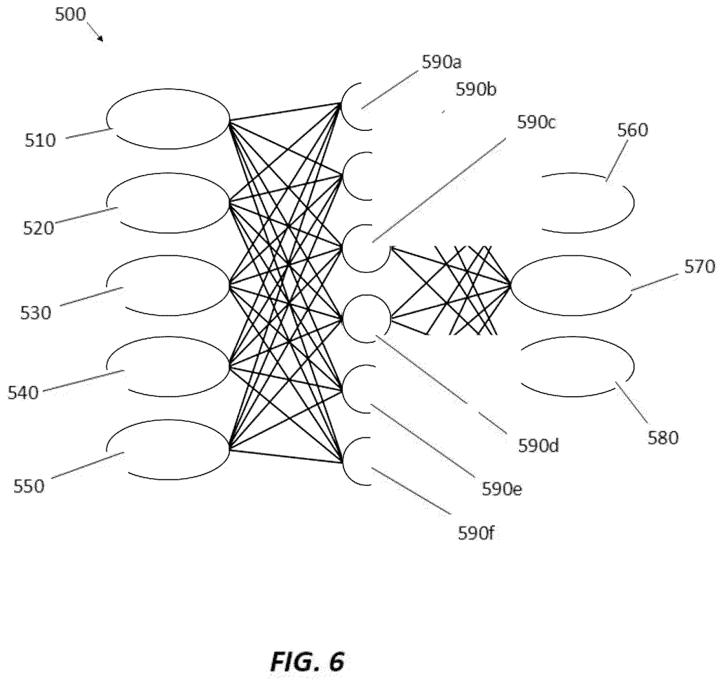

FIG. 6 illustrates a neural network 500 that may be used in the crystal growth machine learning system. The neural network 500 may include input nodes such as a gradient temperature node 510, a melt temperature node 520, a rotation speed node 530, a pull speed node 540, and a mass node 550. These input nodes may connect to hidden layer nodes 590, which in turn may connect to output nodes including a yield output node 560, a length output node 570, and a defects output node 580.

If multiple crystal growth equipment stations are running similar processes, the stations will be networked such that data from each station may be integrated into the machine learning system. The data from an individual station may be analyzed with historical data from that station or with historical and/or real-time data from similar stations. The system further includes a user interface for displaying real-time data, comparison of real-time data to historical data, analysis of individual and/or grouped equipment stations, process trends, root-cause analysis of defects, correlation of process parameters to material properties and output results, and suggested process improvements.

According to other aspects of the present disclosure, the method may include at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer as part of the plurality of sensors. The control modules include process control systems, power output, programmable logic controllers (PLCs), proportional-integral-derivative (PID), digital or analog input controls, motor controls, valve controls, temperature controls, gas flow controls, pressure controls, water controls. The machine learning algorithm may be selected from the group consisting of Linear Regression, Deep Learning, Physics-Informed, Logistic Regression, Neural Network, Classification, and Decision Tree algorithms. The data from the sensors may be hardwired or wirelessly transmitted to the computing system. The machine learning algorithms may be configured to make data-based decisions using historical data, crowdsourced data, and experiential knowledge. The machine learning algorithms may incorporate theoretical equations and may be guided or configured based on physical, chemical, thermodynamic, and mechanical interactions related to the crystal growth process. The user interface may be accessible via a close-loop on-site network, secure web login, or a phone app interface. The user interface may be configured to display real-time data for each running crystal growth setup including plots of measurements, likelihood of success, and dials for manual adjustment of controls. The user interface may display analysis in the form of text or visualizations including pair plots, scatter plots, bar charts, line charts, histograms, box plots, heatmaps, regression analysis plots, feature importances plot, recursive feature elimination plots, elbow plots, scree plots, learning curves, and validation curves.

The crystal growth machine learning system may offer several potential benefits, including reduced reliance on manual monitoring, improved yield, and faster process optimization. By leveraging real-time data analysis and machine learning algorithms, the system may enable more efficient and consistent crystal growth production across various industries.

In some cases, the crystal growth system 300 may include various components that work together to optimize crystal growth processes. The crystal growth system 300 may comprise sensors, data acquisition devices, computing systems, and user interfaces, which may form an integrated architecture for monitoring and improving crystal growth.

The crystal growth system 300 may include a plurality of sensors integrated into the crystal growth equipment for continuous monitoring. These sensors may be capable of measuring various parameters related to the crystal growth process. In some cases, the sensors may include thermometers for measuring temperatures at different points in the crystal growth diagram 100, such as the temperature of the heater 103, the melt 104, or the crystal 102. Additional sensors may measure parameters such as pressure, rotation speed, or crystal mass.

In some implementations, the sensors in the crystal growth system 300 may be wired or wirelessly transmitted to a data acquisition device. This data acquisition device may collect and consolidate data from multiple sensors, enabling comprehensive monitoring of the crystal growth process.

The crystal growth system 300 may include a central computer installed in the crystal growth department. This central computer may serve as the primary computing system for processing and analyzing the data collected by the sensors and data acquisition devices. The central computer may host the machine learning interface 340, which may process input data from the crystal growth module 310, manufacturing module 320, and process engineering module 330.

In some cases, the crystal growth system 300 may feature a user interface for displaying real-time data, process trends, and suggested process improvements. This user interface may be accessible through a web browser or a dedicated application, allowing operators and engineers to monitor and control the crystal growth process remotely.

The architecture of the crystal growth system 300 may be designed to facilitate continuous data flow and analysis. As shown in the process comparison diagram 400, the Crystal Growth ML System configuration may enable rapid processing and feedback, potentially reducing process engineering time from weeks to seconds.

In some implementations, the machine learning interface 340 may utilize algorithms such as the neural network 500 to analyze input data and generate optimized process parameters. The neural network 500 may process inputs such as gradient temperature, melt temperature, rotation speed, pull speed, and mass to predict outputs like yield, crystal length, and potential defects.

The integrated architecture of the crystal growth system 300 may allow for real-time monitoring, analysis, and adjustment of crystal growth processes. This system may potentially enable more efficient and consistent crystal production compared to traditional methods, as illustrated in the crystal growth diagram 100 and the vapor deposition system 150.

The crystal growth system 300 may include a plurality of sensors integrated into the crystal growth equipment for continuous monitoring and data collection. In some cases, these sensors may be positioned at various points within the crystal growth diagram 100 to measure critical parameters throughout the growth process. The crystal growth system 300 may include at least one control module for controlling crystal growth.

For example, thermometers may be installed to measure temperatures at different stages of the crystal growth process, such as the temperature of the heater 103, the melt 104, or the crystal 102 during various growth stages from the first growth stage 111 through the final growth stage 115. Additional sensors may include viscometers, pH meters, conductivity meters, hygrometers, weight sensors, imaging sensors, position measurement tools, manometers, continuous gas analyzers, velocity sensors, and tachometers.

In some implementations, the sensors may be wired or wirelessly connected to a data acquisition device. This data acquisition device may collect and consolidate data from multiple sensors, enabling comprehensive monitoring of the crystal growth process. The data acquisition device may be part of the crystal growth module 310 in the crystal growth system 300.

The collected data may be transmitted to a computing system, which may be part of the machine learning interface 340. In some cases, the computing system may process and analyze the received data in real-time, allowing for immediate adjustments to the crystal growth process if necessary.

The crystal growth system 300 may include a mechanism for cleaning and sorting the collected data. In some implementations, the data may be categorized into identifying data, which may be specific to a particular crystal growth type or corporation, and machine data, which may be universal to subcategories of crystal growth processes. This sorting process may facilitate more efficient data analysis and machine learning applications.

In some cases, the crystal growth system 300 may incorporate barcoding or radio-frequency identification (RFID) technology to track each crystal growth run. This tracking system may generate a unique identifier for each run, which may be linked to specific information such as the crystal serial number, start date, and the particular growth apparatus, or station, used.

The crystal growth system 300 may also include features for automatically capturing, storing, and linking inspection data to specific crystal growth runs. Inspection data includes measured or observed material properties, characteristics, or features. This capability may allow for comprehensive tracking of each crystal's growth process and subsequent quality assessments. In some implementations, this inspection data may be integrated with the data from the crystal growth module 310 and the manufacturing module 320, providing a complete picture of each crystal's lifecycle from growth to final inspection.

By integrating these various data collection and sensor technologies, the crystal growth system 300 may enable more precise monitoring and control of the crystal growth process. This integrated approach may potentially lead to improvements in crystal quality and production efficiency, as illustrated in the process comparison diagram 400.

The crystal growth system 300 may utilize various machine learning algorithms to analyze collected data and predict process improvements. In some cases, these algorithms may be Python-based, trained classification methods, including Linear Regression, Logistic Regression, Neural Network, and Decision Tree algorithms.

Linear Regression may be used in the crystal growth system 300 to model relationships between continuous variables. For example, this algorithm may analyze the relationship between the temperature of the melt 104 and the growth rate of the crystal 102. In some implementations, Linear Regression may help predict optimal temperature settings for maximizing crystal growth rates.

Logistic Regression may be employed in the crystal growth system 300 for binary classification tasks. In some cases, this algorithm may be used to predict whether a crystal growth run will result in a successful yield based on input parameters such as the temperature of the heater 103 and the rotation speed of the crystal 102.

The crystal growth system 300 may incorporate Neural Network algorithms, such as the neural network 500 illustrated in FIG. 6. The neural network 500 may process inputs from nodes such as the gradient temperature node 510, melt temperature node 520, rotation speed node 530, pull speed node 540, and mass node 550. These inputs may be processed through hidden layer nodes 590 to generate outputs at the yield output node 560, length output node 570, and defects output node 580. In some implementations, this neural network structure may enable the crystal growth system 300 to predict complex, non-linear relationships between input parameters and crystal growth outcomes.

Decision Tree algorithms may be utilized in the crystal growth system 300 for both classification and regression tasks. In some cases, these algorithms may help identify the most important factors influencing crystal quality or yield. For example, a Decision Tree may analyze data from various stages of the crystal growth diagram 100 to determine which parameters have the greatest impact on the final crystal quality.

In some implementations, the crystal growth system 300 may store non-specific machine and process data in a cloud-based system. This cloud storage may be used for crowdsourcing to enhance the system's machine learning effectiveness. By aggregating data from multiple sources, the crystal growth system 300 may potentially improve its predictive capabilities and adapt to a wider range of crystal growth scenarios.

The crystal growth system 300 may incorporate historical data, crowdsourced data, and experiential knowledge to guide decisions. In some cases, this comprehensive approach may allow the system to leverage past successes, industry-wide trends, and expert insights in its decision-making process. For example, when analyzing data from the crystal growth module 310, the system may compare current growth parameters to historical data from successful crystal growth runs to suggest potential improvements.

By utilizing these machine learning algorithms and diverse data sources, the crystal growth system 300 may be capable of continuous learning and adaptation. In some implementations, this may lead to ongoing improvements in crystal growth processes, potentially resulting in higher yields and better quality crystals across various growth methods and materials.

In some cases, this user interface may be accessible through a secure web login or a dedicated phone application, allowing authorized personnel to monitor and control crystal growth processes remotely.

The user interface may display real-time data for each active crystal growth setup. In some implementations, this data may include plots of various measurements collected by the system's sensors. The interface may also present a likelihood of success for each ongoing crystal growth process, based on the current parameters and historical data analysis. Additionally, the interface may feature dials or controls for manual adjustment of growth parameters, enabling operators to make real-time modifications if necessary.

In some cases, the user interface may provide statistics for individual growth stations within a facility. These statistics may be organized by station number and may include the GPS location of each station. This feature may allow for easy identification and tracking of multiple crystal growth processes occurring simultaneously across a production facility.

The crystal growth system's user interface may also incorporate manufacturing data, providing real-time feedback on crystals currently in production. In some implementations, this integration of growth and manufacturing data may enable a more comprehensive view of the entire crystal production process, from initial growth to final product inspection.

The system may be designed to provide notifications of process variances and alerts. In some cases, these notifications may be pushed out instantaneously through the web login interface and to linked mobile devices. This feature may allow for rapid response to any deviations or issues in the crystal growth process, potentially reducing the risk of failed growth runs or quality issues.

In some implementations, the user interface may display trends linking growth parameters to crystal yield and defects. These trends may be continuously updated as new crystal growth and manufacturing data becomes available. This feature may assist in identifying patterns and relationships that may not be immediately apparent, potentially leading to process improvements and higher yields over time.

The crystal growth system may also incorporate root-cause analysis capabilities within its user interface. In some cases, this feature may help identify the underlying causes of defects or yield issues by analyzing historical data and current process parameters. The system may then present these findings through the user interface, potentially assisting operators and engineers in addressing recurring problems more effectively.

In some implementations, the user interface may provide suggested process improvements based on its analysis of collected data and identified trends. These suggestions may be presented in a clear, actionable format, potentially allowing for rapid implementation of optimizations to the crystal growth process.

The crystal growth system 300 may provide real-time process alerts and notifications during crystal growth. In some cases, these alerts may be generated by the machine learning interface 340 based on data collected from the crystal growth module 310. For example, if the temperature of the melt 104 in the crystal growth diagram 100 suddenly deviates from the expected range, the system may immediately notify operators through the user interface.

In some implementations, parameter controls may be automatically adjusted based on in-process measurements and historical data analysis. The crystal growth system 300 may analyze data from current growth processes and compare it to historical data stored in the process engineering module 330. Based on this analysis, the system may make automatic adjustments to parameters such as the temperature of the heater 103 or the rotation speed of the crystal 102 to optimize growth conditions.

The crystal growth system 300 may output real-time alerts when measured variables drastically or suddenly change during the process. For instance, if the weight sensor detects an unexpected change in the mass of the growing crystal 102, the system may generate an immediate alert. This rapid response capability may allow operators to address potential issues before they lead to failed growth runs or defective crystals.

In some cases, the crystal growth system 300 may utilize the neural network 500 to predict optimal process parameters and identify potential defects. The neural network 500 may process inputs from nodes such as the gradient temperature node 510 and the rotation speed node 530 to generate outputs at the yield output node 560 and the defects output node 580. These predictions may be used to guide in-process adjustments and improve overall crystal quality.

The process comparison diagram 400 may illustrate the benefits of the crystal growth system 300 compared to traditional methods. While traditional approaches may require weeks for process engineering adjustments, the crystal growth system 300 may enable rapid, data-driven optimizations on a timescale of seconds. This increased speed and efficiency may lead to higher yields and more consistent crystal quality across multiple growth runs.

In some implementations, the crystal growth system 300 may facilitate run-to-run improvements by analyzing data from completed growth processes. The system may identify trends and patterns across multiple runs, potentially leading to incremental optimizations of growth parameters. For example, the system may determine that slight adjustments to the temperature gradient during the second growth stage 112 consistently result in improved crystal quality.

The crystal growth system 300 may also aid in defect elimination by correlating growth parameters with observed defects. By analyzing data from the manufacturing module 320, the system may identify specific conditions that tend to produce defects. This information may be used to adjust growth parameters in subsequent runs, potentially reducing defect rates over time.

In some cases, the crystal growth system 300 may optimize the transition between different growth stages, such as from the seed immersion stage 109 to the growth initiation stage 110. The system may analyze historical data to determine the optimal timing and parameter adjustments for these transitions, potentially leading to more consistent and higher-quality crystal growth.

The crystal growth system 300 may also be applied to different crystal growth methods, such as the vapor deposition system 150. In these cases, the system may adapt its algorithms and sensor inputs to optimize parameters specific to vapor deposition, such as gas pressure and substrate temperature.

By integrating real-time monitoring, automated adjustments, and data-driven optimization, the crystal growth system 300 may offer significant advantages over traditional crystal growth methods. These improvements may lead to increased efficiency, higher yields, and more consistent crystal quality across various growth processes and materials.

The crystal growth system 300 may be applied to various crystal growth methods, including the Czochralski method illustrated in the crystal growth diagram 100 of FIG. 1. The Czochralski method may be a widely used technique for growing large single crystals, particularly in the semiconductor industry.

In some cases, the Czochralski process may begin with the melting stage 107, where the feed material 106 is heated in the crucible 105 using the heater 103 until it forms the melt 104. The crystal growth system 300 may monitor the temperature of the melt 104 using sensors integrated into the crystal growth module 310. In some implementations, the machine learning interface 340 may analyze historical data to determine the optimal melting temperature for specific materials.

The process may continue with the seed lowering stage 108, where the seed crystal 101 is positioned above the melt 104. The crystal growth system 300 may use position sensors to precisely control the distance between the seed crystal 101 and the melt 104 surface. In some cases, the machine learning interface 340 may adjust the lowering speed based on data from previous successful growth runs.

During the seed immersion stage 109, the seed crystal 101 may be brought into contact with the melt 104. The crystal growth system 300 may monitor parameters such as the temperature gradient between the seed crystal 101 and the melt 104, as well as the initial formation of the crystal-melt interface. In some implementations, the neural network 500 may process inputs from the gradient temperature node 510 and the melt temperature node 520 to optimize the conditions for seed immersion.

The growth initiation stage 110 may follow, where the crystal 102 begins to form as the seed crystal 101 is slowly withdrawn from the melt 104. The crystal growth system 300 may continuously monitor and adjust parameters such as the pull speed and rotation rate of the crystal 102. In some cases, the machine learning interface 340 may analyze data from the rotation speed node 530 and the pull speed node 540 to maintain optimal growth conditions.

As the crystal 102 continues to grow, the process may progress through the first growth stage 111, second growth stage 112, third growth stage 113, and fourth growth stage 114. Throughout these stages, the crystal growth system 300 may monitor various parameters, including the diameter of the crystal 102, the weight of the growing crystal, and the shape of the crystal-melt interface. In some implementations, the system may use imaging sensors to capture real-time data on the crystal shape and size.

The machine learning interface 340 may continuously analyze data from the crystal growth module 310 and compare it to historical data stored in the process engineering module 330. This analysis may allow the system to make real-time adjustments to growth parameters, potentially improving crystal quality and yield. For example, if the system detects a deviation in the crystal diameter during the second growth stage 112, the machine learning interface 340 may adjust the pull speed or melt temperature to correct the issue.

In some cases, the crystal growth system 300 may use the neural network 500 to predict potential defects before they occur. By processing inputs from nodes such as the mass node 550 and the pull speed node 540, the system may generate outputs at the defects output node 580, allowing for preemptive adjustments to the growth process.

The final growth stage 115 may involve carefully separating the fully grown crystal 102 from the melt 104. The crystal growth system 300 may control the cooling rate and separation process to minimize thermal stress on the crystal 102. In some implementations, the machine learning interface 340 may analyze data from previous growth runs to optimize the separation parameters for different crystal materials and sizes.

Throughout the entire Czochralski process, the crystal growth system 300 may collect and analyze data from multiple sensors and control systems. This comprehensive monitoring may allow for continuous optimization of the growth process, potentially leading to higher quality crystals and improved yields. In some cases, the system may identify correlations between growth parameters and crystal quality that may not be immediately apparent to human operators, leading to novel insights and process improvements.

By applying machine learning techniques to the Czochralski method, the crystal growth system 300 may potentially enhance the efficiency and reliability of crystal production across various industries. The system's ability to adapt to different materials and growth conditions may make the Czochralski method more versatile and cost-effective for a wide range of applications.

The crystal growth system 300 may also be applied to other crystal growth methods, such as the vapor deposition system 150 illustrated in FIG. 2. Vapor deposition may be a process used to produce high-purity, high-performance solid materials, particularly in the semiconductor and optical industries.

In some cases, the vapor deposition system 150 may include a chamber containing a SiC seed positioned above SIC powder. The crystal growth module 310 may incorporate sensors to monitor various parameters within this chamber, such as temperature, pressure, and gas composition. The heater 103 in the vapor deposition system 150 may be arranged along the sides of the chamber to provide controlled heating.

The crystal growth system 300 may utilize pyrometers positioned at the top and bottom of the chamber for temperature measurement. In some implementations, these pyrometers may provide real-time temperature data to the machine learning interface 340. The machine learning interface 340 may analyze this data to optimize the temperature gradient within the chamber, potentially improving crystal growth conditions.

The vapor deposition system 150 may also incorporate numerical modeling of the temperature field, as shown in the right portion of FIG. 2. This modeling may provide a visualization of the temperature distribution within the chamber, with colors representing different temperature ranges. In some cases, the crystal growth system 300 may use this temperature field data as input for the neural network 500.

The neural network 500 may process temperature data from various points in the vapor deposition chamber, potentially using nodes similar to the gradient temperature node 510 and the melt temperature node 520. The hidden layer nodes 590 may then analyze this data to predict optimal growth conditions and potential defects.

In some implementations, the machine learning interface 340 may compare the measured temperature data from the pyrometers with the numerical modeling results. This comparison may allow the crystal growth system 300 to refine the accuracy of the temperature modeling over time, potentially leading to more precise control of the vapor deposition process.

The crystal growth system 300 may use the temperature field data to make real-time adjustments to the vapor deposition process. For example, if the system detects an uneven temperature distribution, the machine learning interface 340 may adjust the power output of individual heating elements to achieve a more uniform temperature field.

In some cases, the crystal growth system 300 may analyze the relationship between temperature distribution patterns and crystal quality. This analysis may be used to optimize the temperature gradient for specific materials or desired crystal properties. The system may store this information in the process engineering module 330 for use in future vapor deposition runs.

The vapor deposition system 150 may also benefit from the continuous monitoring and optimization capabilities of the crystal growth system 300. The process comparison diagram 400 may illustrate how the integration of machine learning can reduce process engineering time from weeks to seconds, potentially leading to faster optimization of vapor deposition processes.

By applying the crystal growth system 300 to vapor deposition processes, manufacturers may potentially achieve more consistent crystal quality and higher yields. The system's ability to integrate temperature measurement, numerical modeling, and machine learning algorithms may provide a comprehensive approach to optimizing vapor deposition crystal growth.

The crystal growth system 300 may be implemented in industrial settings to optimize crystal growth processes and improve overall production efficiency. In some cases, the system may be integrated into existing crystal growth facilities, enhancing the capabilities of traditional crystal growth methods such as the Czochralski method illustrated in the crystal growth diagram 100 or the vapor deposition system 150.

The crystal growth module 310 of the crystal growth system 300 may incorporate sensors and data acquisition devices throughout the crystal growth process. In some implementations, these sensors may monitor parameters such as the temperature of the melt 104, the rotation speed of the crystal 102, and the pull speed during various growth stages from the melting stage 107 to the final growth stage 115. This comprehensive data collection may enable more precise control and optimization of the crystal growth process.

The manufacturing module 320 may collect data on crystal quality and yield after the growth process. In some cases, this module may analyze parameters such as crystal size, defect concentration, and optical properties. By linking this data to specific growth runs, the crystal growth system 300 may identify correlations between growth conditions and final product quality.

The process engineering module 330 may store historical data and expert knowledge, which may be used by the machine learning interface 340 to inform decision-making and process optimization. In some implementations, this module may also incorporate crowdsourced data from multiple crystal growth facilities, potentially enhancing the system's ability to optimize processes across different materials and growth conditions.

The machine learning interface 340 may utilize algorithms such as the neural network 500 to analyze data from the crystal growth module 310, manufacturing module 320, and process engineering module 330. In some cases, the neural network 500 may process inputs from nodes such as the gradient temperature node 510 and the rotation speed node 530 to predict outputs at the yield output node 560 and the defects output node 580. This analysis may enable the system to make real-time adjustments to growth parameters and predict potential issues before they occur.

The process comparison diagram 400 may illustrate one of the primary benefits of implementing the crystal growth system 300 in industrial settings. While traditional crystal growth processes may require weeks for process engineering adjustments, the crystal growth system 300 may enable rapid, data-driven optimizations on a timescale of seconds. This reduction in process engineering time may lead to faster iteration and optimization of crystal growth processes.

In some implementations, the crystal growth system 300 may improve yield by identifying optimal growth conditions for specific materials and crystal types. By analyzing data from multiple growth runs, the system may determine the ideal parameters for each stage of the crystal growth process, from the seed immersion stage 109 to the final growth stage 115. This optimization may result in a higher percentage of usable crystal material and reduced waste.

The crystal growth system 300 may also enhance safety in industrial crystal growth settings. By providing continuous monitoring and real-time alerts, the system may detect potential issues such as temperature anomalies or unexpected changes in crystal growth rate. In some cases, this early detection may allow operators to address problems before they escalate into safety hazards or result in equipment damage.

The implementation of the crystal growth system 300 may lead to more consistent crystal quality across multiple growth runs. By reducing reliance on individual operator expertise and standardizing processes based on data-driven insights, the system may minimize variations in crystal properties and defect rates. This consistency may be particularly beneficial for industries requiring high-precision crystals, such as semiconductor manufacturing or optical component production.

In some cases, the crystal growth system 300 may facilitate the development of new crystal materials or growth techniques. By analyzing vast amounts of data and identifying non-obvious correlations between growth parameters and crystal properties, the system may suggest novel approaches to crystal growth that may not be apparent through traditional experimentation methods.

The crystal growth system 300 may also contribute to energy efficiency in industrial crystal growth processes. By optimizing heating patterns and growth rates, the system may reduce the overall energy consumption required for crystal production. In some implementations, this may lead to cost savings and reduced environmental impact of crystal growth operations.

By implementing the crystal growth system 300, industrial facilities may potentially achieve a more streamlined and efficient crystal growth operation. The system's ability to integrate data from multiple sources, provide real-time analysis, and suggest process improvements may lead to significant advancements in crystal growth technology across various industries.

The system includes a software package that integrates data collection, ML algorithms, and data analysis to provide real-time notifications and alerts, production trends, root-cause identification, and suggested process improvements for crystal growth processes. This solution replaces the need for continuous labor monitoring of crystal growth stations, improves the yield and profitability of crystal growth production, provides data storage and automated data-driven continuous improvements that reduce the process engineering time and effort required by technical staff, and reduces cost, risk, rework, and training time required for crystal growth production methods.

In one embodiment of the system includes continuous monitoring by sensors integrated into the crystal growth equipment and real-time process alerts and notifications during crystal growth. Parameter controls are automatically adjusted based on in-process measurements and historical data analysis. Inspection data is automatically captured, stored, and linked to specific crystal growth runs. ML algorithms are employed to identify trends in crystal growth production, link yield to process variables, conduct robust root-cause analysis of crystal defects, and predict process improvements. FIG. 3 shows the system 300 including data inputs from crystal growth 310, manufacturing 320, and process engineering 330 to the Crystal Growth ML System 340. Outputs include instantaneous (in-process) adjustments during crystal growth, text alerts of anomalies or problems in growth, and a web user interface empowering root-cause analysis, defect elimination, trend identification, process improvements, and run-to-run adjustments. This system saves time and cost of run failures by making automatic in-process adjustments and/or alerting staff of anomalies immediately. In contrast, without the system in place, crystal growth runs may be failing or causing catastrophic risks until a technician notices, wasting time and creating safety risks. This system also drastically reduces the process engineering time required between crystal growth runs and improves the chances of effective yield improvements and defect elimination.

FIG. 5 displays the current state of the art 410 at the top of the chart with data flowing one way and weeks of engineering time 416 required for crystal growth 412 run-to-run adjustments. In contrast, the Crystal Growth ML System 4418 shown at the bottom of the chart allows data to flow continuously for crystal growth 420 with process engineering time 424 between runs 422 accomplished in seconds. This allows for engineering resources to focus on new aspects 428 including business, product development, materials research and development, expansion of product lines and capabilities, and major yield improvements.

Sensors, Data, and Controls—Barcoding or RF identification is used to track each crystal growth run. Information associated with each crystal growth run is keyed to the crystal serial number, start date, and specific growth apparatus, triangulated by GPS, that is automatically generated/identified at the initiation of a new run. Initial setup data includes raw starting material composition, purity, weight, volume, seed crystal composition and orientation, and crucible shape, size, and material. Depending on the desired crystal and size, the system automatically sets process controls based on historical data.

The system includes sensors that are installed in crystal growth production areas. Based on type of crystal growth and material, these sensors include a viscometer, pH meter, conductivity meter, thermometers (thermostats, thermistors, thermocouples, and infrared temperature sensors to measure the temperature of the furnace, melt, gradient, environment, and annealing), hygrometer, weight sensors (digital scales or load cell measurement of melt and/or crystal mass), imaging sensors to measure interface shape and/or size of crystal (by diameter of reflection at the crystal growth interface), position measurement tools (linear sensors, interferometers to measure crystal size), manometer to measure internal pressure, continuous gas analyzer, velocity sensors (to measure rotation and growth rate), and tachometer. The sensors are wired or wirelessly transmitted to a data acquisition device, linked to a computing system, and stored on a secure, virtual network.

Crystal growth data is cleaned and sorted into identifying data (specific to a crystal growth type and/or corporation) and machine data (universal to subcategories of crystal growth processes). Within a corporation, crystal growth data is keyed to specific serial numbers for traceability throughout the manufacturing process. Non-specific machine and process data is stored in a cloud used for crowdsourcing to enhance the system's ML effectiveness.

Machine Learning Algorithm—The ML algorithms are the functional basis of the crystal growth system. Python-based, trained, classification methods are used. Linear and Logistic Regression, Neural Network, and Decision Tree algorithms are employed in the system. The system inputs descriptors include crystal growth setup information, process control parameters, and measured process variables from installed sensors. Depending on the type of crystal and growth method, these descriptors vary. Similarly, output variables of percent yield, optical inspection values, and defect identification depend on the type of crystal material and product testing. FIG. 6 shows a diagram of a neural network algorithm 500 used for Czochralski crystal growth of an optical crystal. The input variables are Temperature 510 (Gradient), Temperature 520 (Melt), Speed 530 (Rotation), Speed 540 (Pull), and Mass 550. The hidden layer shown by purple nodes 590a-590f contain functions and weighted biases that are adjusted as the model is trained. the output variables are percent yield 560 (usable material after optical inspection), length 570, and defects 580.

Historical data, from iterations and previous crystal growth runs, crowdsourced data, and experiential knowledge are incorporated to guide the system and make data-based decisions. The system outputs include real-time alerts (of a measured variable drastically or suddenly changing during the process) and process control adjustments, identification of process trends and root-cause of defects, and suggested process improvements for run-to-run adjustments to optimize yield and minimize defects.

Network Design and System User Interface—A central computer is installed into the crystal growth department, which receives growth data from sensors and is accessible by the web user interface. Multiple tabs contain information on current runs and machine learning data. The user interface displays real-time data for each running crystal growth setup including plots of measurements, likelihood of success, and dials for manual adjustment of controls. The user interface also displays statistics for each growth station, identified by number and GPS location, and the department overall. Manufacturing data is visible in the user interface, giving the crystal growth department real-time feedback of crystals currently in production. This feedback is a significant advancement to the current status quo of separated data tracking within departments. The trends linking growth parameters to crystal yield and defects are displayed, updated continuously with addition of crystal growth and manufacturing data. This user interface is accessible by secure web login or phone app interface. Notifications of process variances and alerts are pushed out, instantaneously, over the web login and linked phones.

The Crystal Growth ML System presented here provides significant advancements to the crystal growth industry. This invention delivers instantaneous alerts and crystal growth process analysis and improvements on a time scale that is not possible by human capabilities, thus relieving the effects of the labor gap and improving the current production engineering methods used in crystal growth.

According to an aspect of the present disclosure, a crystal growth optimization system includes a plurality of sensors integrated into crystal growth equipment for continuous monitoring and data collection. The system also includes a data acquisition device for receiving data from the sensors, a computing system for storing and processing the received data, and a machine learning algorithm implemented on the computing system for analyzing the received data and predicting process improvements. The system further includes a user interface for displaying real-time data, process trends, root-cause analysis of defects, and suggested process improvements.

According to other aspects of the present disclosure, the system may include at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer as part of the plurality of sensors. The machine learning algorithm may be selected from the group consisting of Linear Regression, Logistic Regression, Neural Network, and Decision Tree algorithms. The user interface may be accessible via a secure web login or a phone app interface. The data acquisition device may be configured to wirelessly transmit data from the sensors to the computing system. The machine learning algorithm may be configured to make data-based decisions using historical data, crowdsourced data, and experiential knowledge. The user interface may be configured to display real-time data for each running crystal growth setup including plots of measurements, likelihood of success, and dials for manual adjustment of controls.

According to another aspect of the present disclosure, a method for optimizing crystal growth includes monitoring a crystal growth process using a plurality of sensors integrated into crystal growth equipment, collecting data from the sensors, storing and processing the collected data on a computing system, analyzing the collected data using a machine learning algorithm implemented on the computing system to identify process trends and root-cause of defects, predicting process improvements based on the analysis, and displaying the real-time data, process trends, root-cause analysis of defects, and suggested process improvements on a user interface.

According to other aspects of the present disclosure, the method may include at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer as part of the plurality of sensors. The machine learning algorithm may be selected from the group consisting of Linear Regression, Logistic Regression, Neural Network, and Decision Tree algorithms. The data from the sensors may be wirelessly transmitted to the computing system. The machine learning algorithm may be configured to make data-based decisions using historical data, crowdsourced data, and experiential knowledge. The user interface may be accessible via a secure web login or a phone app interface. The user interface may be configured to display real-time data for each running crystal growth setup including plots of measurements, likelihood of success, and dials for manual adjustment of controls.

According to yet another aspect of the present disclosure, a crystal growth optimization system includes a plurality of sensors for monitoring a crystal growth process and collecting data, a data acquisition device for receiving the collected data, a computing system for storing and processing the received data, a machine learning algorithm implemented on the computing system for analyzing the received data, identifying process trends and root-cause of defects, and predicting process improvements, and a user interface for displaying the real-time data, process trends, root-cause analysis of defects, and suggested process improvements. The system automatically adjusts process controls based on in-process measurements and historical data analysis.

According to other aspects of the present disclosure, the system may include sensors configured to monitor at least one of temperature, pressure, pH, conductivity, viscosity, and weight during the crystal growth process. The data acquisition device may be configured to receive data from the sensors in real-time. The machine learning algorithm may be configured to analyze the received data and predict process improvements based on a comparison of the received data with historical data. The user interface may be configured to display the real-time data, process trends, root-cause analysis of defects, and suggested process improvements in a graphical format. The system may be configured to automatically adjust process controls based on the analysis of the machine learning algorithm, thereby optimizing the crystal growth process.

The method or methods described above may be executed or carried out by a computing system including a tangible computer-readable storage medium, also described herein as a storage machine, that holds machine-readable instructions executable by a logic machine (i.e. a processor or programmable control device) to provide, implement, perform, and/or enact the above-described methods, processes and/or tasks. When such methods and processes are implemented, the state of the storage machine may be changed to hold different data. For example, the storage machine may include memory devices such as various hard disk drives, CD, or DVD devices. The logic machine may execute machine-readable instructions via one or more physical information and/or logic processing devices. For example, the logic machine may be configured to execute instructions to perform tasks for a computer program. The logic machine may include one or more processors to execute the machine-readable instructions. The computing system may include a display subsystem to display a graphical user interface (GUI) or any visual element of the methods or processes described above. For example, the display subsystem, storage machine, and logic machine may be integrated such that the above method may be executed while visual elements of the disclosed system and/or method are displayed on a display screen for user consumption. The computing system may include an input subsystem that receives user input. The input subsystem may be configured to connect to and receive input from devices such as a mouse, keyboard or gaming controller. For example, a user input may indicate a request that certain task is to be executed by the computing system, such as requesting the computing system to display any of the above-described information, or requesting that the user input updates or modifies existing stored information for processing. A communication subsystem may allow the methods described above to be executed or provided over a computer network. For example, the communication subsystem may be configured to enable the computing system to communicate with a plurality of personal computing devices. The communication subsystem may include wired and/or wireless communication devices to facilitate networked communication. The described methods or processes may be executed, provided, or implemented for a user or one or more computing devices via a computer-program product such as via an application programming interface (API).

Since many modifications, variations, and changes in detail can be made to the described embodiments of the invention, it is intended that all matters in the foregoing description and shown in the accompanying drawings be interpreted as illustrative and not in a limiting sense. Furthermore, it is understood that any of the features presented in the embodiments may be integrated into any of the other embodiments unless explicitly stated otherwise. The scope of the invention should be determined by the appended claims and their legal equivalents.

In addition, the present invention has been described with reference to embodiments, it should be noted and understood that various modifications and variations can be crafted by those skilled in the art without departing from the scope and spirit of the invention. Accordingly, the foregoing disclosure should be interpreted as illustrative only and is not to be interpreted in a limiting sense. Further it is intended that any other embodiments of the present invention that result from any changes in application or method of use or operation, method of manufacture, shape, size, or materials which are not specified within the detailed written description or illustrations contained herein are considered within the scope of the present invention.

Insofar as the description above and the accompanying drawings disclose any additional subject matter that is not within the scope of the claims below, the inventions are not dedicated to the public and the right to file one or more applications to claim such additional inventions is reserved.

Although very narrow claims are presented herein, it should be recognized that the scope of this invention is much broader than presented by the claim. It is intended that broader claims will be submitted in an application that claims the benefit of priority from this application.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A system for crystal growth optimization, comprising:
a plurality of sensors integrated into crystal growth equipment for continuous monitoring and data collection;
a data acquisition device for receiving data from the sensors;
a computing system for storing and processing the received data;
a plurality of control modules for controlling the components within the system;
a machine learning algorithm implemented on the computing system for analyzing the received data and predicting process improvements; and
a user interface for displaying real-time data, process trends, root-cause analysis of defects, and suggested process improvements.

2. The system of claim 1, wherein the plurality of sensors includes at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer.

3. The system of claim 1, wherein the machine learning algorithm is selected from the group consisting of Linear Regression, Logistic Regression, Neural Network, and Decision Tree algorithms.

4. The system of claim 1, further comprising a mechanism for automatically adjusting crystal growth parameters based on the predicted process improvements.

5. The system of claim 4, wherein the automatically adjusted crystal growth parameters include at least one of temperature, rotation speed, pull speed, and pressure.

6. The system of claim 1, further comprising a data storage system for storing historical crystal growth data and crowdsourced data from multiple crystal growth facilities.

7. The system of claim 6, wherein the machine learning algorithm uses the historical crystal growth data and crowdsourced data to enhance prediction accuracy of process improvements across different materials and growth conditions.

8. A method for optimizing crystal growth, comprising:
continuously monitoring crystal growth parameters using a plurality of sensors integrated into crystal growth equipment;
using at least one control module for controlling crystal growth;
collecting data from the sensors using a data acquisition device;
processing the collected data using a computing system;
analyzing the processed data using a machine learning algorithm to predict process improvements; and
displaying real-time data, process trends, root-cause analysis of defects, and suggested process improvements on a user interface.

9. The method of claim 8, wherein the plurality of sensors includes at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer.

10. The method of claim 8, wherein the machine learning algorithm is selected from the group consisting of Linear Regression, Logistic Regression, Neural Network, and Decision Tree algorithms.

11. The method of claim 8, further comprising a step of automatically adjusting crystal growth parameters based on the predicted process improvements.

12. The method of claim 11, wherein the automatically adjusted crystal growth parameters include at least one of temperature, rotation speed, pull speed, and pressure.

13. The method of claim 8, further comprising a step of storing historical crystal growth data and crowdsourced data from multiple crystal growth facilities in a data storage system.

14. The method of claim 13, wherein the machine learning algorithm utilizes the historical crystal growth data and crowdsourced data to enhance prediction accuracy of process improvements across different materials and growth conditions.

15. A non-transitory computer-readable medium storing instructions that, when executed by a processor, cause the processor to perform operations for crystal growth optimization, the operations comprising:
receiving data from a plurality of sensors integrated into crystal growth equipment;
storing and processing the received data;
analyzing the processed data using a machine learning algorithm to predict process improvements; and
generating output for display on a user interface, the output including real-time data, process trends, root-cause analysis of defects, and suggested process improvements.

16. The non-transitory computer-readable medium of claim 15, wherein the plurality of sensors includes at least one of a viscometer, a pH meter, a conductivity meter, a thermometer, a hygrometer, a weight sensor, an imaging sensor, a position measurement tool, a manometer, a continuous gas analyzer, a velocity sensor, and a tachometer.

17. The non-transitory computer-readable medium of claim 15, wherein the machine learning algorithm is selected from the group consisting of Linear Regression, Logistic Regression, Neural Network, and Decision Tree algorithms.

18. The non-transitory computer-readable medium of claim 15, wherein the operations further comprise automatically adjusting crystal growth parameters based on the predicted process improvements.

19. The non-transitory computer-readable medium of claim 18, wherein the automatically adjusted crystal growth parameters include at least one of temperature, rotation speed, pull speed, and pressure.

20. The non-transitory computer-readable medium of claim 19, wherein the operations further comprise storing historical crystal growth data and crowdsourced data from multiple crystal growth facilities, and wherein the machine learning algorithm utilizes the historical crystal growth data and crowdsourced data to enhance prediction accuracy of process improvements across different materials and growth conditions.
